(19) United States
(12) Patent Application Publication
(10) Pub. No.: US 2026/0068753 A1
(43) Pub. Date: Mar. 5, 2026

(54) CHIP PACKAGING STRUCTURE AND METHOD FOR FORMING THE SAME

(71) Applicant: YANGTZE MEMORY TECHNOLOGIES CO., LTD., Wuhan (CN)

(72) Inventors: Shanshan Zhao, Wuhan (CN); Baohua Zhang, Wuhan (CN); Li Tao, Wuhan (CN)

(21) Appl. No.: 18/825,672

(22) Filed: Sep. 5, 2024

(30) Foreign Application Priority Data
Aug. 29, 2024 (CN) 202411205083.8

(51) Int. Cl. H01L 25/065; H01L 21/56; H10B 80/00

(52) U.S. Cl. CPC H01L 25/0657; H10B 80/00

(57) ABSTRACT

A chip packaging structure and fabrication method are provided. The chip packaging structure includes: one or more dies stacked on a packaging substrate in a vertical direction; and a packaging body surrounding the one or more dies. The packaging body includes: a compound layer in direct contact with the one or more dies, where the compound layer includes a material having a reference strength and a reference modulus; a first layer adjacent to a top surface of the packaging body, where the first layer includes a material having a first strength and a first modulus, and the first strength being greater than the reference strength; and a second layer positioned between the first layer and the one or more dies along the vertical direction, where the second layer includes a material having a second strength and a second modulus, and the second modulus being less than the reference modulus.

### CROSS-REFERENCE TO RELATED APPLICATIONS

This application claims the benefit of priority to Chinese Application No. 202411205083.8, filed on Aug. 29, 2024, which is incorporated herein by reference in its entirety.

### TECHNICAL FIELD

The present disclosure relates to semiconductor structure, and in particular, to a chip packaging structure and a fabrication method thereof.

### BACKGROUND

In the semiconductor industry, the performance and reliability of electronic devices are significantly influenced by the packaging structure used to house and protect semiconductor dies. The packaging structure not only provides mechanical support but also plays a crucial role in heat dissipation and electrical performance.

There is ongoing interest in designing semiconductor packaging structures to enhance the overall performance and reliability of semiconductor devices.

### SUMMARY

A first aspect of the present disclosure provides a chip packaging structure. The chip packaging structure includes one or more dies stacked on a packaging substrate in a vertical direction; and a packaging body surrounding the one or more dies. The packaging body includes a compound layer in direct contact with the one or more dies, where the compound layer includes a material having a reference strength and a reference modulus; a first layer adjacent to a top surface of the packaging body, where the first layer includes a material having a first strength and a first modulus, and the first strength being greater than the reference strength; and a second layer positioned between the first layer and the one or more dies along the vertical direction, where the second layer includes a material having a second strength and a second modulus, and the second modulus being less than the reference modulus.

In some implementations, the first layer has a first surface area, the second layer has a second surface area, and the first surface area is larger than the second surface area.

In some implementations, the first layer has a first surface area, the second layer has a second surface area, and the first surface area is smaller than the second surface area.

In some implementations, the packaging body further includes: a third layer attached to the second layer, where the third layer includes a material having a third strength and a third modulus, the third strength being less than the second strength, the second strength being less than the reference strength, the third modulus being less than the second modulus, and the first modulus being greater than the reference modulus.

In some implementations, the packaging body further includes multiple layers attached to the second layer, where: a strength of each of the multiple layers is less than the strength of the second layer, decreasing from a layer furthest from the packaging substrate to a layer closest to the packaging substrate along the vertical direction; and a modulus of each of the multiple layers is less than the second modulus of the second layer, increasing from a layer closest to the packaging substrate to a layer furthest from the packaging substrate along the vertical direction.

In some implementations, the material of the first layer includes a metal alloy, and the material of the second layer includes a polymer.

In some implementations, each of the first layer and the second layer has a thickness in a range of about 30 micrometers to about 100 micrometers.

In some implementations, the one or more dies include at least one of a NAND die or a DRAM die.

In some implementations, the chip packaging structure further includes a controller configured to control the one or more dies, and the controller is positioned on the packaging substrate and beside the one or more dies.

In some implementations, the first strength is equal to or greater less than 190 MPa, and the second modulus is equal to or less than 26 GPa.

In some implementations, the second layer has a curved surface towards the one or more dies.

In some implementations, the second layer covers a bottom surface and side surfaces of the first layer.

In some implementations, the second layer covers a bottom surface of the first layer; and the first layer has curved side surfaces in contact with the compound layer.

A second aspect of the present disclosure provides a chip packaging structure. The chip packaging structure includes: one or more dies on a packaging substrate; and a packaging body surrounding the one or more dies. The packaging body includes a compound layer in direct contact with at least one of the one or more dies, where the compound layer includes a material having a reference strength and a reference modulus; a first layer adjacent to a top surface of the packaging body, where the first layer includes a material having a first strength and a first modulus, and the first strength being greater than the reference strength; and a second layer positioned between the first layer and the one or more dies, where the second layer includes a material having a second strength and a second modulus, and the second modulus being less than the reference modulus, where a surface area of the second layer is smaller than a surface area of the first layer.

In some implementations, the packaging body further includes: a third layer positioned between the second layer and the one or more dies, where the third layer includes a material having a third strength and a third modulus, the third strength being less than the second strength, the third modulus being less than the second modulus, and a surface area of the third layer is smaller than the surface area of the second layer.

In some implementations, the packaging body further includes multiple layers attached to the second layer. A strength of each of the multiple layers is less than the strength of the second layer, decreasing from a layer furthest from the packaging substrate to a layer closest to the packaging substrate along the vertical direction; and a modulus of each of the multiple layers is less than the second modulus of the second layer, increasing from a layer closest to the packaging substrate to a layer furthest from the packaging substrate along the vertical direction.

In some implementations, the material of the first layer includes a metal alloy, and the material of the second layer includes a polymer.

In some implementations, each of the first layer and the second layer has a thickness in a range of about 30 micrometers to about 100 micrometers.

In some implementations, the one or more dies include at least one of a NAND die or a DRAM die.

In some implementations, the chip packaging structure further includes a controller configured to control the one or more dies, and the controller is positioned on the packaging substrate and beside the one or more dies.

In some implementations, the first strength is equal to or greater than 190 MPa, and the second modulus is equal to or less than 26 GPa.

In some implementations, the second layer has a curved surface towards the one or more dies; the second layer covers a bottom surface of the first layer; and the first layer has curved side surfaces in contact with the compound layer.

A third aspect of the present disclosure provides a method of forming a chip packaging structure. The method includes: stacking one or more dies on a packaging substrate in a vertical direction; and forming a packaging body surrounding the one or more dies. The packaging body includes: a compound layer in direct contact with the one or more dies, where the compound layer includes a compound material having a reference strength and a reference modulus; a first layer adjacent to a top surface of the packaging body, where the first layer includes a material having a first strength and a first modulus, and the first strength being greater than the reference strength; and a second layer positioned between the first layer and the one or more dies along the vertical direction, where the second layer includes a material having a second strength and a second modulus, and the second modulus being less than the reference modulus.

In some implementations, forming the packing body includes: forming a first layer in a mold; forming a second layer attached to the first layer along the vertical direction; filling the mold with the compound material; placing the one or more dies into the compound material; and transforming the compound material into the compound layer.

In some implementations, forming the packing body further includes: forming the first layer having a first surface area; and forming the second layer having a second surface area, where the first surface area is larger than the second surface area.

In some implementations, forming the packing body further includes: forming the first layer having a first surface area; and forming the second layer having a second surface area, where the first surface area is smaller than the second surface area.

In some implementations, forming the packaging body further includes: before filling the mold with the compound material, forming a third layer attached to the second layer, where the third layer includes a material having a third strength and a third modulus, the third strength being less than the second strength, and the third modulus being less than the second modulus.

In some implementations, forming the packaging body further includes: before filling the mold with the compound material, forming multiple layers attached to the second layer, where: a strength of each of the multiple layers is less than the strength of the second layer, decreasing from a layer furthest from the packaging substrate to a layer closest to the packaging substrate along the vertical direction; and a modulus of each of the multiple layers is less than the second modulus of the second layer, increasing from a layer closest to the packaging substrate to a layer furthest from the packaging substrate along the vertical direction.

In some implementations, forming the first layer includes forming a metal alloy layer, and forming the second layer includes forming a polymer layer.

In some implementations, forming the metal alloy layer includes forming the metal alloy layer with a thickness in a range of about 30 micrometers to about 100 micrometers, and forming the polymer layer includes forming the polymer layer with a thickness in a range of about 30 micrometers to about 100 micrometers.

In some implementations, stacking the one or more dies on the packaging substrate includes stacking at least one of a NAND die or a DRAM die, and forming the chip packaging structure further includes forming a controller on the packaging substrate, where the controller is configured to control the one or more dies.

In some implementations, forming the second layer includes forming the second layer with a curved surface towards the one or more dies.

In some implementations, forming the second layer includes forming the second layer covering a bottom surface and side surfaces of the first layer.

In some implementations, forming the second layer includes forming the second layer covering a bottom surface of the first layer; and forming the first layer includes forming the first layer with curved side surfaces.

### BRIEF DESCRIPTION OF THE DRAWINGS

The accompanying drawings, which are incorporated herein and form a part of the specification, illustrate aspects of the present disclosure and, together with the description, further explain the present disclosure and enable a person skilled in the pertinent art to make and use the present disclosure.

FIG. 1a illustrates a cross-sectional view of a first chip packaging structure in accordance with some implementations of the present disclosure.

FIG. 1b illustrates a cross-sectional view of a second chip packaging structure in accordance with some implementations of the present disclosure.

FIG. 1c illustrates a cross-sectional view of a third chip packaging structure in accordance with some implementations of the present disclosure.

FIG. 1d illustrates a cross-sectional view of a fourth chip packaging structure in accordance with some implementations of the present disclosure.

FIG. 1e illustrates a cross-sectional view of a fifth chip packaging structure in accordance with some implementations of the present disclosure.

FIG. 2a and FIG. 2a′ illustrate side view (X-Z plane) and top view (X-Y plane), respectively, of a chip packaging structure in accordance with some implementations of the present disclosure.

FIG. 2b and FIG. 2b′ illustrate side view (Y-Z) and top view (X-Y plane), respectively, of a chip packaging structure in accordance with some implementations of the present disclosure.

FIGS. 3a-3g and FIG. 3g′ are schematic diagrams of operations of a method for manufacturing a chip packaging structure according to an implementation of the present disclosure.

FIG. 4 is a schematic flowchart of a method for manufacturing a chip packaging structure.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures, or characteristics in a plural sense. Similarly, terms, such as “a,” “an,” or “the,” may be understood to convey a singular usage or to convey a plural usage, depending at least in part upon context. In addition, the term “based on” may be understood as not necessarily intended to convey an exclusive set of factors and may, instead, allow for the existence of additional factors not necessarily expressly described, depending at least in part on the context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, “bond pad” is a term generally referring to electrical bond pads in association with test points or external electrical connections of an integrated electronic device such as an integrated circuit (IC) or Micro-Electro-Mechanical System device. Related industry terms are “bonding pad” and “bump. ” As used herein, “solder bump” or “solder ball” are terms generally referring to a ball of solder bonded to a bond pad for further assembly of the die into packages by the use of surface mount technology or wire bonding.

As used herein, the term “die” generally refers to a small piece of a processed semiconductor wafer that is diced into sections containing integrated circuits or other devices. The term “die stack” generally refers to a vertical assembly of two or more dies containing integrated circuits that are interconnected to function as a unit.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as glass, plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductor and contact layers (in which interconnect lines and/or via contacts are formed) and one or more dielectric layers.

As used herein, the term “nominal/nominally” refers to a desired, or target, value of a characteristic or parameter for a component or a process operation, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

As used herein, the term “connected” refers to a direct connection, such as an electrical or mechanical connection between the things that are connected, without any intermediary devices.

As used herein, the term “circuit” may refer to one or more passive and/or active components that are arranged to cooperate with one another to provide a desired function. The term “IC” is a microelectronic circuit produced monolithically on semiconductor wafer substrates by microfabrication methods.

As used herein, the term “edge misaligned” generally refers to a stack of dies having one or more edges misaligned horizontally or laterally from each other.

As used herein, the term “top surface” refers to the surface of a structure that is the farthest away from the substrate the structure is formed on/in, and the term “bottom surface” refers to the surface of a structure that is the closest to the substrate the structure is formed on/in. In the present disclosure, the relative positions of the top surface and the bottom surface do not change as the orientation of the object changes.

In the present disclosure, the elevation of a surface of an object is defined as the distance between the surface and the substrate on/in which the object is formed. In the present disclosure, the relative position of the two surfaces is defined based on the elevations of the two surfaces and does not change as the orientation of the objects change.

As used herein, the terms “stair,” “step,” and “level” can be used interchangeably. As used herein, a staircase structure refers to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A “stair” refers to a vertical shift in the height of a set of adjoined surfaces. A “staircase structure” refers to a structure having a plurality of stairs extending vertically.

As used herein, the terms “first,” “second,” etc., are used to distinguish similar objects, and are not necessarily used to describe a specific order or sequence.

It should be noted that the technical solutions described in the implementations of the present disclosure may be combined arbitrarily if there is no conflict.

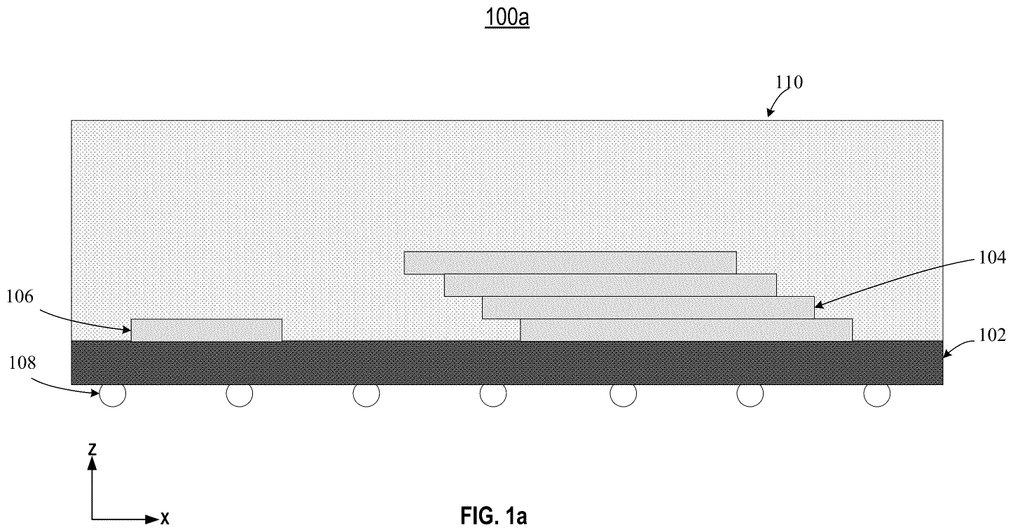

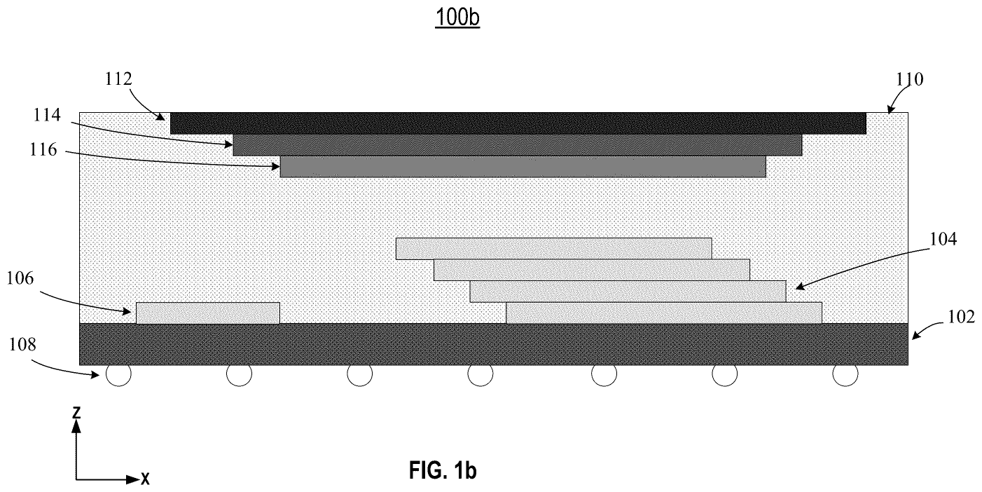

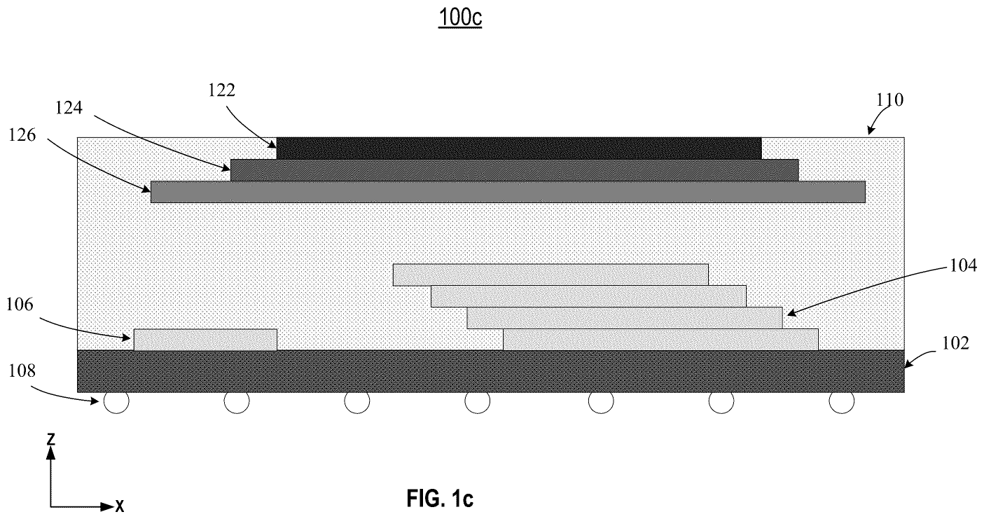

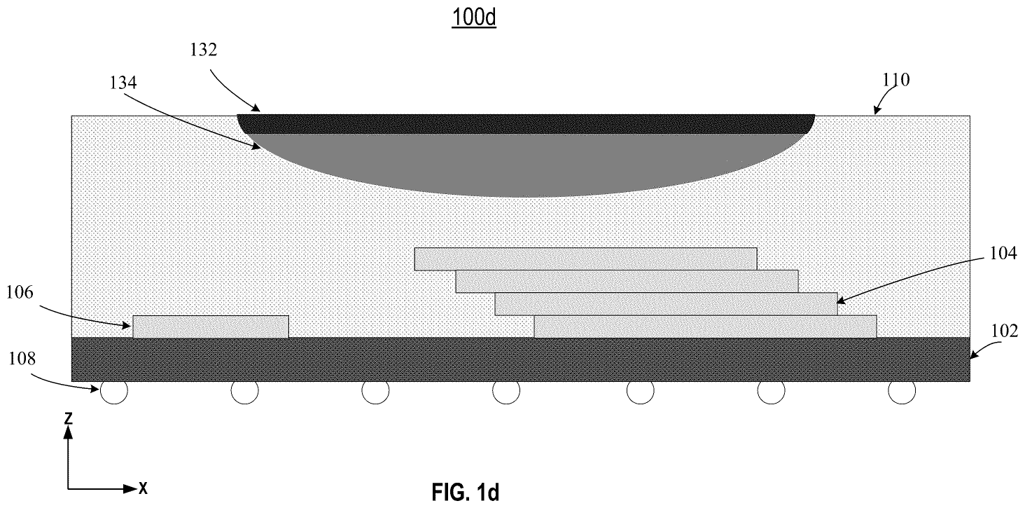

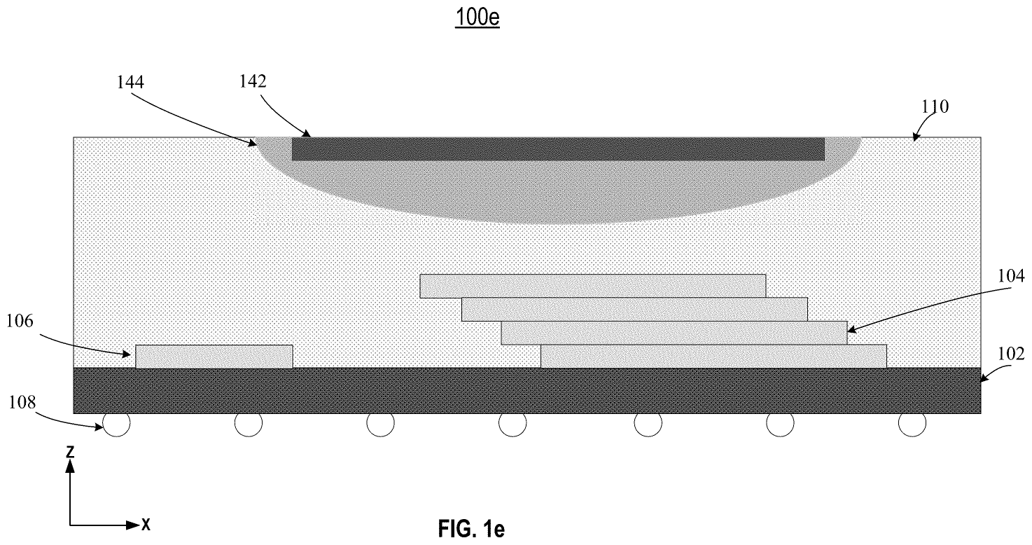

FIG. 1a illustrates a cross-sectional view of a first chip packaging structure 100a in accordance with some implementations of the present disclosure. The chip packaging structure 100a includes a substrate 102, on which multiple dies 104 are stacked in a vertical direction (e.g., Z direction as shown in FIG. 1a) and misaligned in a lateral direction (e.g., X direction as shown in FIG. 1a). In some implementations, the one or more dies 104 can be arranged in different configurations such as side-by-side or staggered on the packaging substrate 102, depending on the design requirements and space constraints. These alternative arrangements can help optimize the layout for thermal management, signal integrity, and overall performance of the chip packaging structure.

As shown in FIG. 1a, a compound layer 110 is in direct contact with the one or more dies 104. The compound layer 110 includes a material having a reference strength and a reference modulus, providing necessary support and encapsulation for the one or more dies 104. The reference strength may be in a range of about 170 MPa to about 220 MPa, for example, about 170 MPa, 180 MPa, 190 MPa, 200 MPa, 210 MPa, or 220 MPa. The reference modulus may be in a range of about 20 GPa to about 30 GPa, for example, about 20 GPa, 21 GPa, 22 GPa, 23 GPa, 24 GPa, 25 GPa, 26 GPa., 27 GPa, 28 GPa, 29 GPa, or 30 GPa. Positioned on the packaging substrate 102 and beside the one or more dies 104 is a controller 106, which is configured to control the operation of the one or more dies 104, ensuring proper functionality of the chip packaging structure 100a. Additionally, solder balls 108 are attached to the bottom surface of the packaging substrate 102. These solder balls 108 facilitate electrical connections between the chip packaging structure 100a and an external circuit board.

In the chip packaging structure 100a as shown in FIG. 1a, enhancements can be made to further improve the performance of the chip packaging structure.

FIG. 1b illustrates a cross-sectional view of a second chip packaging structure 100b in accordance with some implementations of the present disclosure. Building upon the design shown in FIG. 1a, the chip packaging structure 100b includes additional layers for enhanced performance. The chip packaging structure 100b as shown in FIG. 1b maintains the same fundamental components as the chip packaging structure 100a as shown in FIG. 1a, including the packaging substrate 102, the one or more dies 104, the compound layer 110, the controller 106, and the solder balls 108.

In addition to these components, as shown in FIG. 1b, the chip packaging structure 100b incorporates a first layer 112 adjacent to a top surface of the compound layer 110. The first layer 112 includes a material having a first strength greater than the reference strength, enhancing the overall strength of the packaging structure. In some implementations, the first layer 112 may be made from a metal alloy such as a copper alloy, an aluminum alloy, a titanium alloy, or the like, which is not limited herein. In some implementations, the first layer 112 may also be made from a high-modulus polymer, which is not limited herein. The thickness of the first layer 112 may range from about 30 μm to about 100 μm.

Positioned between the first layer 112 and the one or more dies 104 along the vertical direction is a second layer 114. The second layer 114 includes a material having a second modulus less than the reference modulus, helping to manage mechanical stresses. In some implementations, the second layer 114 may be made from a Die Attach Film (DAF), or a low-modulus polymer such as silicone or polyurethane, etc., which is not limited herein. The thickness of the second layer 114 may range from about 30 μm to about 100 μm.

In some implementations, the first layer 112 has a first surface area, while the second layer 114 has a second surface area, with the second surface area being smaller than the first surface area.

Furthermore, the chip packaging structure 100b may include a third layer 116 attached to the second layer 114 and positioned between the second layer 114 and the one or more dies 104. The third layer 116 may be made from a material having a third strength and a third modulus, where the third strength is less than the second strength, and the third modulus is less than the second modulus. This configuration ensures that the third layer 116, similar to the second layer 114, helps to manage mechanical stresses effectively. In some implementations, the third layer 116 has a third surface area, with the third surface area being less than the second surface area of the second layer 114, which further contributes to the distribution of mechanical stresses, enhancing the overall stability and robustness of the chip packaging structure 100b. This arrangement of the third layer 116, along with the first and second layers, forms an inverted triangle configuration that optimizes the mechanical properties of the packaging structure.

The chip packaging structure 100b may include multiple layers attached to the second layer 114, enhancing its mechanical performance. The strength of each of these multiple layers is less than the strength of the second layer 114, with the strength decreasing from the layer furthest from the packaging substrate 102 to the layer closest to the packaging substrate 102 along the vertical direction. Conversely, the modulus of each of these multiple layers is less than the second modulus of the second layer 114, with the modulus increasing from the layer closest to the packaging substrate 102 to the layer furthest from the packaging substrate 102 along the vertical direction. This configuration ensures a gradual distribution of mechanical properties, optimizing stress management and enhancing the overall stability and robustness of the chip packaging structure 100b. In some implementations, the surface area of each layer in FIG. 1b decreases from the layer furthest from the packaging substrate 102 to the layer closest to the packaging substrate 102 along the vertical direction, further contributing to the effective management of mechanical stresses.

FIG. 1c illustrates a cross-sectional view of a third chip packaging structure 100c in accordance with some implementations of the present disclosure. Building upon the design shown in FIG. 1a, the chip packaging structure 100c includes additional layers for enhanced performance. The chip packaging structure 100c as shown in FIG. 1c maintains the same fundamental components as the chip packaging structure 100a as shown in FIG. 1a, including the packaging substrate 102, the one or more dies 104, the compound layer 110, the controller 106, and the solder balls 108.

In addition to these components, as shown in FIG. 1c, the chip packaging structure 100c incorporates a first layer 122 adjacent to a top surface of the compound layer 110. The first layer 122 includes a material having a first strength greater than the reference strength of the compound layer 110, enhancing the overall strength of the packaging structure. In some implementations, the first layer 122 may be made from a metal alloy such as a copper alloy, an aluminum alloy, a titanium alloy, or the like, which is not limited herein. In some implementations, the first layer 122 may also be made from a high-modulus polymer, which is not limited herein. The thickness of the first layer 122 may range from about 30 μm to about 100 μm.

Positioned between the first layer 122 and the one or more dies 104 along the vertical direction is a second layer 124. The second layer 124 includes a material having a second modulus less than the reference modulus, helping to manage mechanical stresses. In some implementations, the second layer 124 may be made from a Die Attach Film (DAF), or a low-modulus polymer such as silicone or polyurethane, etc., which is not limited herein. The thickness of the second layer 124 may range from about 30 μm to about 100 μm.

In some implementations, the first layer 122 has a first surface area, while the second layer 124 has a second surface area, with the second surface area being larger than the first surface area.

Furthermore, the chip packaging structure 100c may include a third layer 126 attached to the second layer 124 and positioned between the second layer 124 and the one or more dies 104. The third layer 126 may be made from a material having a third strength and a third modulus, where the third strength is less than the second strength, and the third modulus is less than the second modulus. This configuration ensures that the third layer 126, similar to the second layer 124, helps to manage mechanical stresses effectively. In some implementations, the third layer 126 has a third surface area, with the third surface area being larger than the second surface area of the second layer 124, which further contributes to the distribution of mechanical stresses, enhancing the overall stability and robustness of the chip packaging structure 100c. This arrangement of the third layer 126, along with the first and second layers, forms a triangle configuration that optimizes the mechanical properties of the packaging structure.

The chip packaging structure 100c may include multiple layers attached to the second layer 124, enhancing its mechanical performance. The strength of each of these multiple layers is less than the strength of the second layer 124, with the strength decreasing from the layer furthest from the packaging substrate 102 to the layer closest to the packaging substrate 102 along the vertical direction. Conversely, the modulus of each of these multiple layers is less than the second modulus of the second layer 124, with the modulus increasing from the layer closest to the packaging substrate 102 to the layer furthest from the packaging substrate 102 along the vertical direction. This configuration ensures a gradual distribution of mechanical properties, optimizing stress management and enhancing the overall stability and robustness of the chip packaging structure 100c. In some implementations, the surface area of each layer in FIG. 1c decreases from the layer furthest from the packaging substrate 102 to the layer closest to the packaging substrate 102 along the vertical direction, further contributing to the effective management of mechanical stresses.

FIG. 1d illustrates a cross-sectional view of a fourth chip packaging structure 100d in accordance with some implementations of the present disclosure. Building upon the design shown in FIG. 1a, the chip packaging structure 100d includes additional layers for enhanced performance. The chip packaging structure 100d as shown in FIG. 1d maintains the same fundamental components as the chip packaging structure 100a as shown in FIG. 1a, including the packaging substrate 102, the one or more dies 104, the compound layer 110, the controller 106, and the solder balls 108.

In addition to these components, as shown in FIG. 1d, the chip packaging structure 100d incorporates a first layer 132 adjacent to a top surface of the compound layer 110. The first layer 132 includes a material having a first strength greater than the reference strength, enhancing the overall strength of the packaging structure. In some implementations, the first layer 132 may be made from a metal alloy such as a copper alloy, an aluminum alloy, a titanium alloy, or the like, which is not limited herein. In some implementations, the first layer 132 may also be made from a high-modulus polymer, which is not limited herein. The thickness of the first layer 132 may range from about 30 μm to about 100 μm. The first layer 132 has two flat surfaces: a first surface facing away from the substrate 102 and a second surface facing towards the substrate 102. In some implementations, the first surface of the first layer 132 has a surface area larger than a surface area of the second surface of the first layer 132.

Positioned between the first layer 132 and the one or more dies 104 along the vertical direction is a second layer 134. The second layer 134 includes a material having a second modulus less than the reference modulus, helping to manage mechanical stresses. In some implementations, the second layer 134 may be made from a Die Attach Film (DAF), or a low-modulus polymer such as silicone or polyurethane, etc., which is not limited herein. The thickness of the second layer 134 may range from about 30 μm to about 100 μm. The second layer 134 has a flat surface in contact with the surface of the first layer that is facing towards the substrate 102, and a curved surface towards the one or more dies 104, forming a concave shape. In some implementations, the flat surface of the second layer 134 has a surface area substantially the same as the surface area of the second surface of the first layer 132. That is, the flat surface of the second layer 134 covers the second surface of the first layer 132, without covering side surfaces of the first layer 132.

FIG. 1e illustrates a cross-sectional view of a fifth chip packaging structure 100e in accordance with some implementations of the present disclosure. Building upon the design shown in FIG. 1a, the chip packaging structure 100e includes additional layers for enhanced performance. The chip packaging structure 100e as shown in FIG. 1e maintains the same fundamental components as the chip packaging structure 100a as shown in FIG. 1a, including the packaging substrate 102, the one or more dies 104, the compound layer 110, the controller 106, and the solder balls 108.

In addition to these components, as shown in FIG. 1e, the chip packaging structure 100e incorporates a first layer 142 adjacent to a top surface of the compound layer 110. The first layer 142 includes a material having a first strength greater than the reference strength, enhancing the overall strength of the packaging structure. In some implementations, the first layer 142 may be made from a metal alloy such as a copper alloy, an aluminum alloy, a titanium alloy, or the like, which is not limited herein. In some implementations, the first layer 142 may also be made from a high-modulus polymer, which is not limited herein. The thickness of the first layer 142 may range from about 30 μm to about 100 μm.

Positioned between the first layer 142 and the one or more dies 104 along the vertical direction is a second layer 144. The second layer 144 includes a material having a second modulus less than the reference modulus, helping to manage mechanical stresses. In some implementations, the second layer 144 may be made from a Die Attach Film (DAF), or a low-modulus polymer such as silicone or polyurethane, etc., which is not limited herein. The thickness of the second layer 144 may range from about 30 μm to about 100 μm. The second layer 144 has a flat surface in contact with the top surface of the compound layer 110 and a curved surface towards the one or more dies 104, forming a concave shape. The second layer 144 covers the bottom surface and side surfaces of the first layer 142.

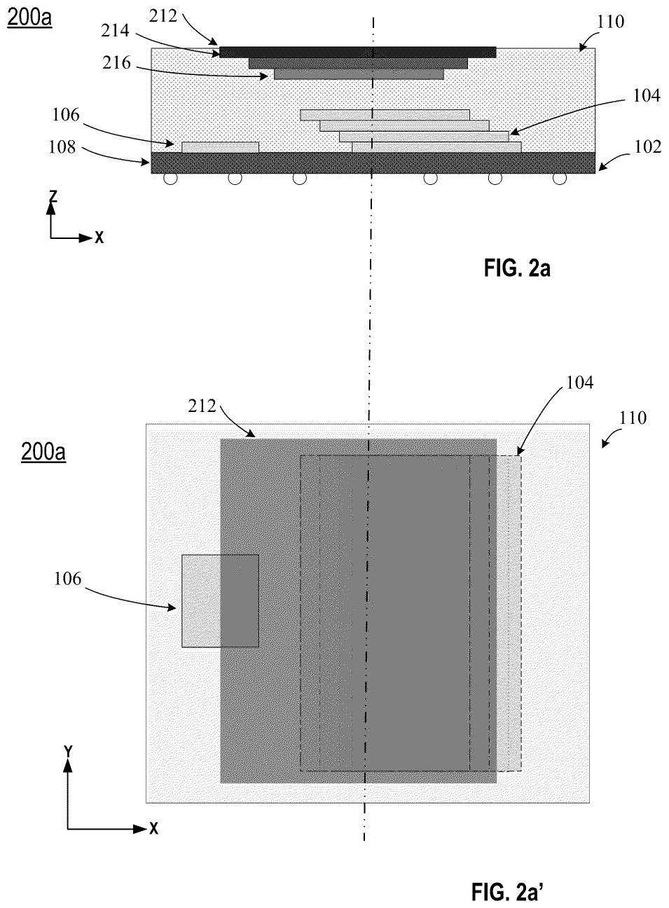

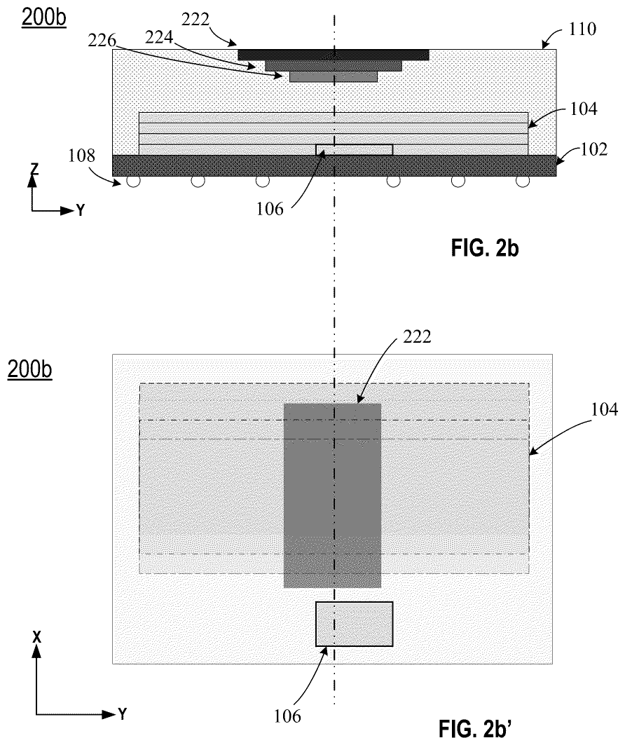

FIG. 2a and FIG. 2a′ illustrate side view (X-Z plane as shown in FIG. 2a) and top view (X-Y plane as shown in FIG. 2a′), respectively, of a chip packaging structure 200a in accordance with some implementations of the present disclosure. Building upon the design shown in FIG. 1a, the chip packaging structure 200a includes additional layers for enhanced performance. The chip packaging structure 200a as shown in FIG. 2a and FIG. 2a′ maintains the same fundamental components as the chip packaging structure 100a as shown in FIG. 1a, including the packaging substrate 102, the one or more dies 104, the compound layer 110, the controller 106, and the solder balls 108.

The chip packaging structure 200a incorporates a first layer 212 adjacent to a top surface of the compound layer 110. The first layer 212 includes a material having a first strength greater than the reference strength of the compound layer 110, thereby enhancing the mechanical strength of the chip packaging structure. The first layer 212 may be made from materials such as metal alloys or high-modulus polymers, and its thickness may range from about 30 μm to about 100 μm. The long edge of the first layer 212 is aligned with the long edge of the one or more dies 204, ensuring a consistent structural layout.

Positioned between the first layer 212 and the one or more dies 104 along the vertical direction is a second layer 214. The second layer 214 includes a material having a second modulus less than the reference modulus of the compound layer 110, helping to manage mechanical stresses. In some implementations, the second layer 214 may be made from a Die Attach Film (DAF), or a low-modulus polymer such as silicone or polyurethane, etc., which is not limited herein. The thickness of the second layer 114 may range from about 30 μm to about 100 μm.

In some implementations, the first layer 212 has a first surface area, while the second layer 214 has a second surface area, with the second surface area being smaller than the first surface area. As shown in FIG. 2a, along the vertical direction (e.g., Z direction as shown in FIG. 2a), the second layer 214 is fully covered by the first layer 212.

Furthermore, the chip packaging structure 200a may include a third layer 216 attached to the second layer 214 and positioned between the second layer 214 and the one or more dies 104. The third layer 116 may be made from a material having a third strength and a third modulus, where the third strength is less than the second strength, and the third modulus is less than the second modulus. This configuration ensures that the third layer 116, similar to the second layer 114, helps to manage mechanical stresses effectively. In some implementations, the third layer 116 has a third surface area, with the third surface area being less than the second surface area of the second layer 114, which further contributes to the distribution of mechanical stresses, enhancing the overall stability and robustness of the chip packaging structure 100b. This arrangement of the third layer 116, along with the first and second layers, forms an inverted triangle configuration that optimizes the mechanical properties of the packaging structure.

FIG. 2a′ provides a top view of the same chip packaging structure 200a. This view highlights the alignment of the long edge of the first layer 212 with the long edge of the dies 204, illustrating the consistent orientation of these components within the packaging structure.

FIG. 2b and FIG. 2b′ illustrate side view (Y-Z plane as shown in FIG. 2b) and top view (X-Y plane as shown in FIG. 2b′), respectively, of a chip packaging structure 200b in accordance with some implementations of the present disclosure. Building upon the design shown in FIG. 1a, the chip packaging structure 200b includes additional layers for enhanced performance. The chip packaging structure 200b as shown in FIG. 2b and FIG. 2b′ maintains the same fundamental components as the chip packaging structure 100a as shown in FIG. 1a, including the packaging substrate 102, the one or more dies 104, the compound layer 110, the controller 106, and the solder balls 108.

The chip packaging structure 200b incorporates a first layer 222 adjacent to a top surface of the compound layer 110. The first layer 222 includes a material having a first strength greater than the reference strength of the compound layer 110, thereby enhancing the mechanical strength of the chip packaging structure. The first layer 222 may be made from materials such as metal alloys or high-modulus polymers, and its thickness may range from about 30 μm to about 100 μm. The longer edge of the first layer 222 is aligned with the shorter edge of the one or more dies 104, ensuring a consistent structural layout.

Positioned between the first layer 222 and the one or more dies 104 along the vertical direction is a second layer 224. The second layer 224 includes a material having a second modulus less than the reference modulus of the compound layer 110, helping to manage mechanical stresses. In some implementations, the second layer 224 may be made from a Die Attach Film (DAF), or a low-modulus polymer such as silicone or polyurethane, etc., which is not limited herein. The thickness of the second layer 214 may range from about 30 μm to about 100 μm.

In some implementations, the first layer 222 has a first surface area, while the second layer 224 has a second surface area, with the second surface area being smaller than the first surface area. As shown in FIG. 2b, along the vertical direction (e.g., Z direction as shown in FIG. 2b), the second layer 224 is fully covered by the first layer 222.

Furthermore, the chip packaging structure 200b may include a third layer 226 attached to the second layer 224 and positioned between the second layer 224 and the one or more dies 104. The third layer 226 may be made from a material having a third strength and a third modulus, where the third strength is less than the second strength, and the third modulus is less than the second modulus. This configuration ensures that the third layer 226, similar to the second layer 224, helps to manage mechanical stresses effectively. In some implementations, the third layer 226 has a third surface area, with the third surface area being less than the second surface area of the second layer 224, which further contributes to the distribution of mechanical stresses, enhancing the overall stability and robustness of the chip packaging structure 200b. This arrangement of the third layer 226, along with the first and second layers, forms an inverted triangle configuration that optimizes the mechanical properties of the packaging structure.

FIG. 2b′ provides a top view of the same chip packaging structure 200b. This view highlights the alignment of the longer edge of the first layer 212 with the shorter edge of the dies 204, illustrating the orientation of these components within the chip packaging structure 200b.

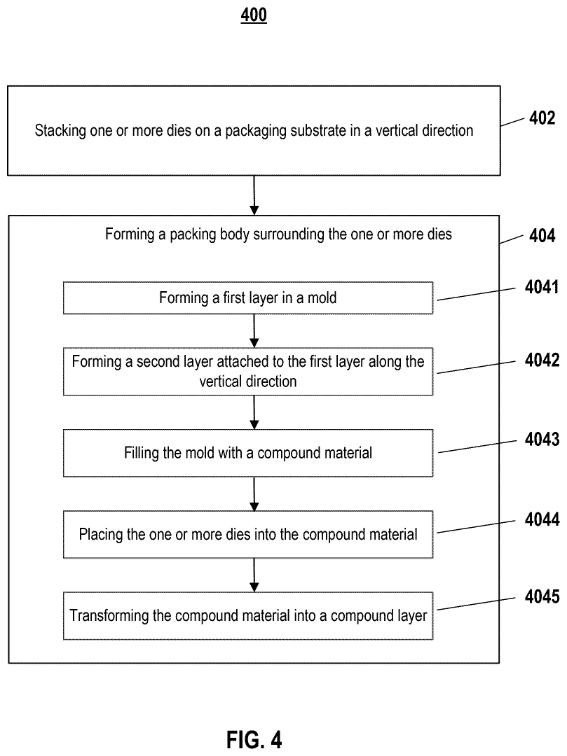

Implementations of the present disclosure provide a method for manufacturing a chip packaging structure. FIG. 4 is a schematic flowchart of a method for manufacturing a chip packaging structure. As shown in FIG. 4, the method includes the following operations.

Operation 402: Stacking one or more dies on a packaging substrate in a vertical direction.

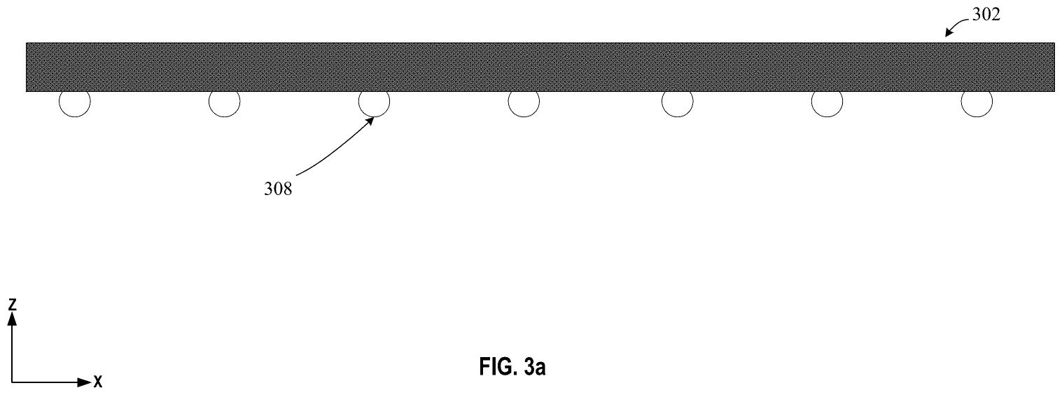

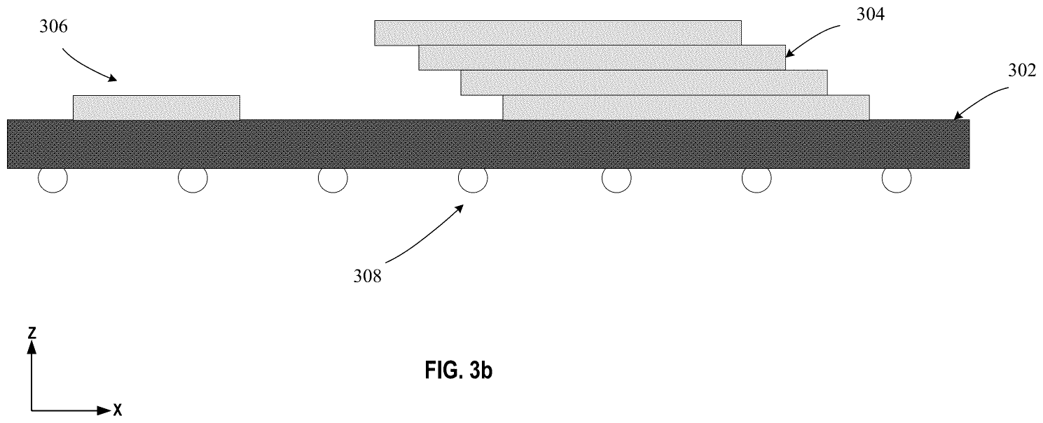

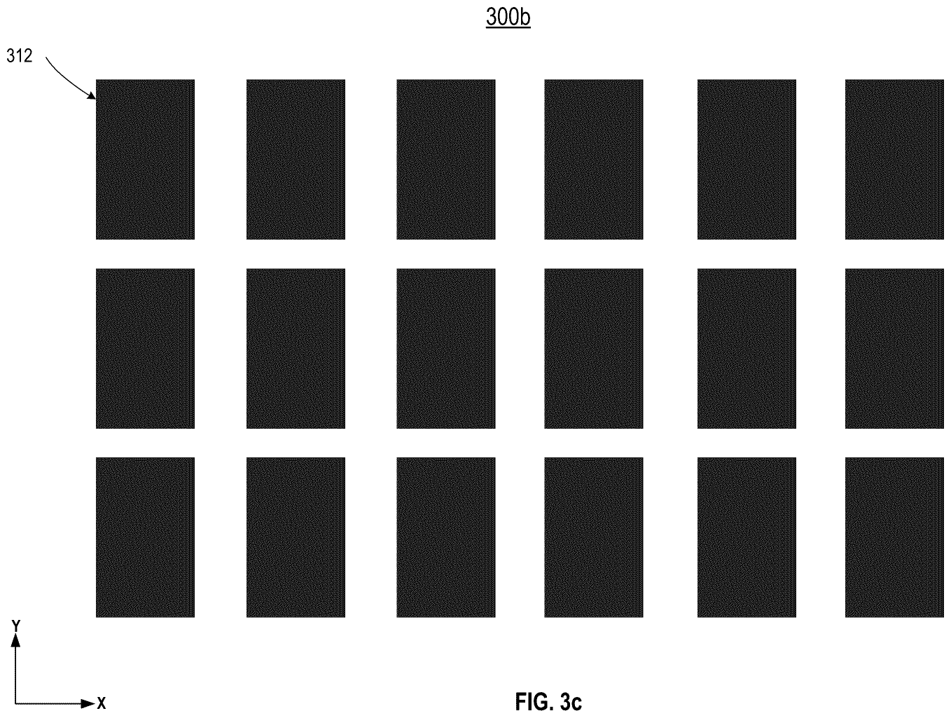

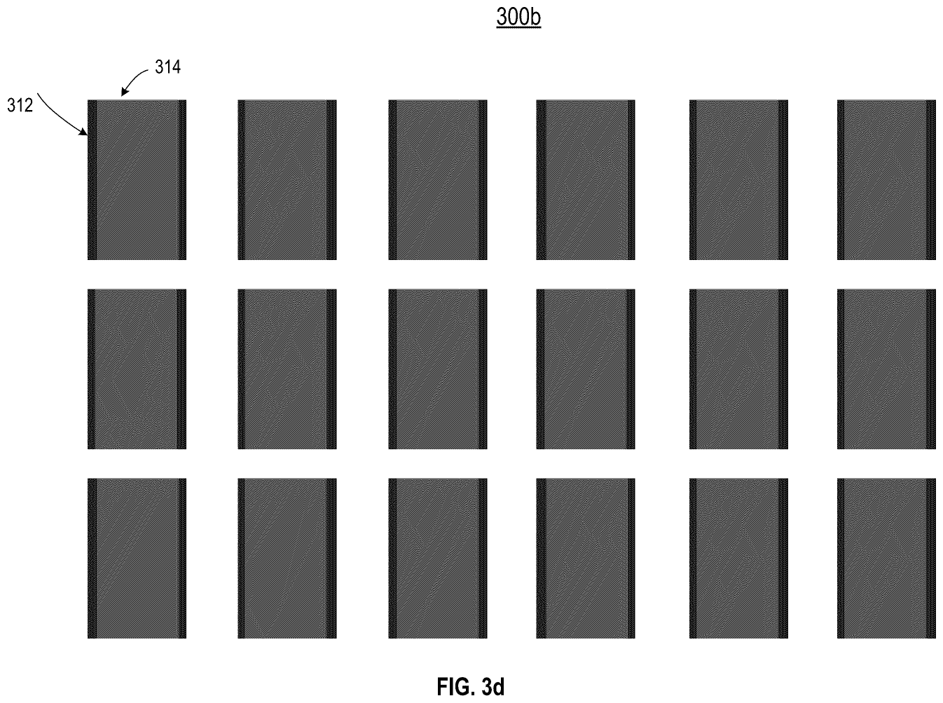

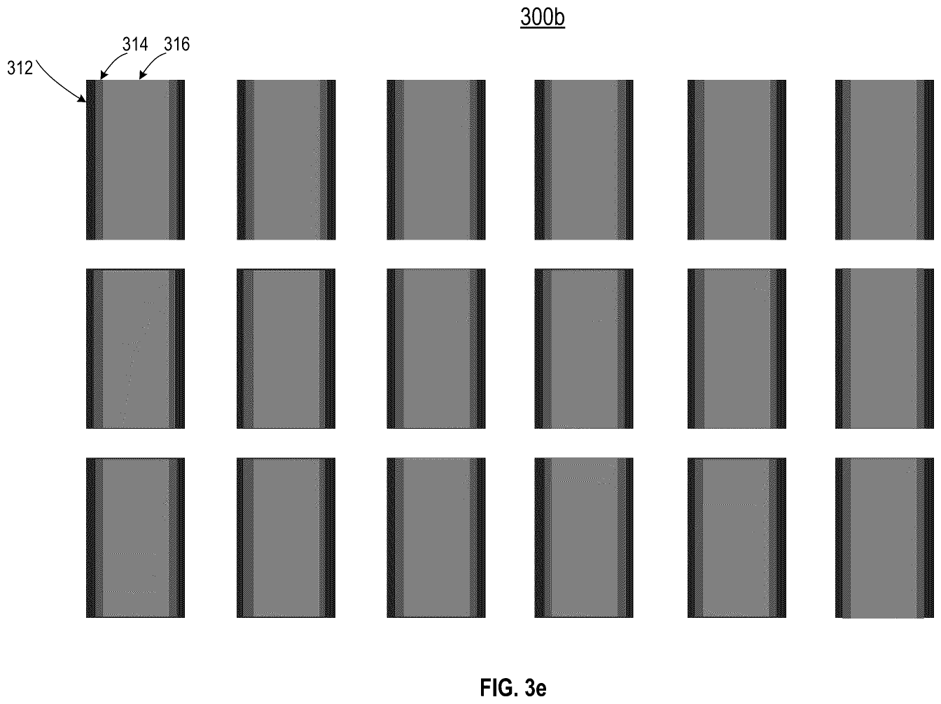

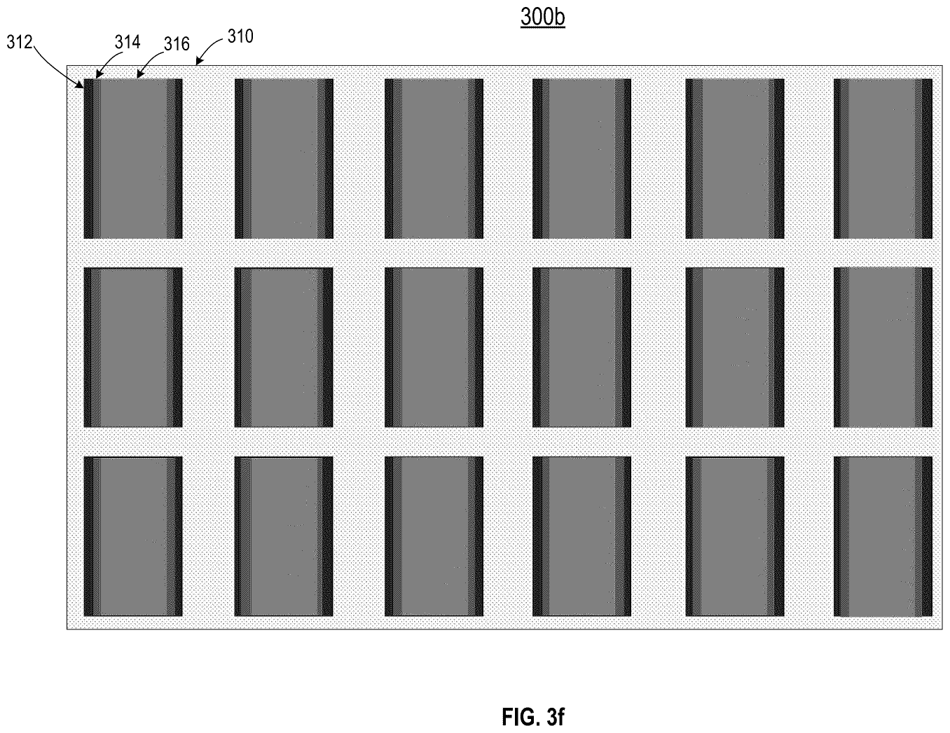

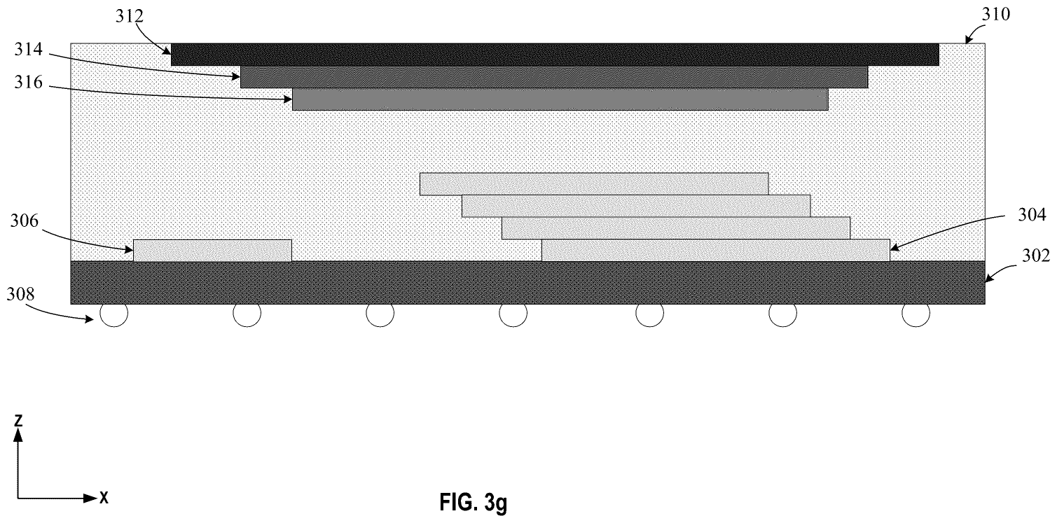

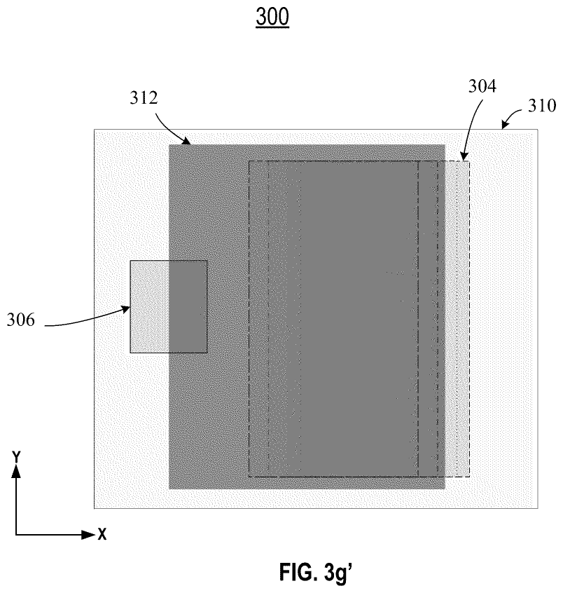

FIG. 3a and FIG. 3b are schematic cross-sectional views of operations of a method stacking one or more dies on a packaging substrate in a vertical direction according to an implementation of the present disclosure. It should be understood that the operations shown in FIG. 3a and FIG. 3b are not exclusive, and other operations may be performed before, after, or between any of the operations. The manufacturing method of stacking one or more dies on a packaging substrate is described below with reference to FIG. 4 and FIG. 3a-FIG. 3b.

As shown in FIG. 3a, a packaging substrate 302 is provided. In some implementations, the packaging substrate 302 (e.g., the packaging substrate 102 in connection with FIG. 1a) may be a carrier substrate made from silicon (e.g., single crystalline silicon, c-Si), silicon germanium (SiGe), gallium arsenide (GaAs), germanium (Ge), silicon on insulator (SOI), or any other suitable materials. In some implementations, packaging substrate 302 may be made from ceramic, glass, or an organic material such as epoxy resin or glass-reinforced epoxy resin, phenolic substrate, or the like.

In some implementations, the packaging substrate 302 may have a plurality of solder ball 308 on the bottom surface of the packaging substrate 302. The solder balls 308 (e.g., the solder ball 108 in connection with FIG. 1a) can be made from materials such as tin-lead alloys, lead-free solders, or high-temperature solder alloys, which ensure reliable electrical connections. These solder balls 308 facilitate the attachment of the chip packaging structure to an external circuit board, providing both mechanical support and electrical connectivity. In some implementations, the solder balls 308 can be used to facilitate heat dissipation by transferring thermal energy away from the packaging substrate 302 to the external circuit board, thereby enhancing the overall thermal management and reliability of the semiconductor device.

As shown in FIG. 3b, one or more dies 304 (e.g., one or more dies 104 in connection with FIG. 1a) may be stacked along a vertical direction (e.g., Z direction as shown in FIG. 3b) on the packaging substrate 302 to form a die assembly 300a. The one or more dies 304 have no specific limitation on quantity. Individual dies may be the same or may be different, and at least one die is a NAND die or a DRAM die. The one or more dies may be stacked by using an adhesive material. In some implementations, the adhesive material may include thermally/electrically conductive metal to facilitate heat dissipation and reduce resistance. Different dies may provide a variety of different functions (e.g., logic, memory, sensors). The dies may have a same thickness, essentially the same thickness, or different thicknesses. The height of the die assembly 300a in the vertical direction is controlled by the thickness of individual dies 304 and the number of dies. The thickness of individual dies 304 may be in the range of about 20 micrometers to about 200 micrometers.

In some implementations, edges of adjacent two dies 304 are misaligned such that an upper one of the adjacent two dies has an extended portion located beyond a lower one of the adjacent two dies. The extended portion of the upper one of the adjacent two dies includes an offset in a lateral direction (e.g., X direction as shown in FIG. 3b) with respect to the lower one of the adjacent two dies. In some implementations, the one or more dies 304 can be arranged in different configurations such as side-by-side or staggered on the packaging substrate 302, depending on the design requirements and space constraints. These alternative arrangements can help optimize the layout for thermal management, signal integrity, and overall performance of the chip packaging structure.

In some implementations, a controller 306 is formed or attached on the packaging substrate 302. The controller 306 (e.g., the controller 106 in connection with FIG. 1a) is positioned beside the one or more dies 304 on the substrate 302. The controller 306 is configured to manage and coordinate the operation of the one or more dies 304, ensuring optimal performance and functionality. It may handle tasks such as data processing, communication control, and power management. Additionally, the controller 306 can facilitate communication between the one or more dies 304 and external devices. In some implementations, the controller 306 may also include error correction capabilities and system monitoring functions to detect and mitigate any operational issues, thereby increasing the reliability and robustness of the chip packaging structure.

Referring back to FIG. 4, the method 400 further includes operation 404, which involves forming a packaging body surrounding the die assembly 300a.

Operation 404 may include the following steps.

Step 4041, forming a first layer in a mold. FIG. 3c illustrates a top view of mold 300b used in the fabrication process of a chip packaging structure in accordance with some implementations of the present disclosure. The mold 300b includes multiple mold cavities, each designated to form a first layer 312 within the mold.

The first layer 312 is deposited in the mold cavities of the mold 300b. The first layer 312 includes a material having a first strength that is higher than a reference strength and a first modulus that is higher than a reference modulus. The reference strength and the reference modulus are the strength and modulus of a compound layer that will be formed later. In some implementations, the first layer 312 may be made from materials such as metal alloys, including copper alloys, aluminum alloys, and titanium alloys, or high-modulus polymers, such as polyimide and polyether ether ketone (PEEK). These materials are selected for their superior mechanical properties, including high tensile strength and modulus, which contribute to the overall robustness of the packaging structure.

The preparation method for the first layer 312 involves depositing a chosen material into the mold cavities of the mold 300b. This can be achieved through various fabrication techniques such as spin coating, sputtering, electroplating, or chemical vapor deposition (CVD), depending on the specific material used. The deposition process ensures that the first layer 312 conforms to the shape of the mold cavities, achieving uniform thickness and consistent mechanical properties across all the layers formed.

Once the first layer 312 is deposited and solidified within the mold 300b, it serves as a foundational component for further assembly in the chip packaging structure, providing enhanced mechanical stability and strength. The multiple mold cavities allow for the simultaneous fabrication of several first layers 312, increasing the efficiency of the manufacturing process. There are 18 mold cavities shown in FIG. 3c. It should be noted that FIG. 3c is only for illustrative purposes. The quantity of mold cavities is not limited herein.

Operation 404 may further include step 4042: forming a second layer attached to the first layer along the vertical direction.

As shown in FIG. 3d, a second layer 314 is formed on top of the first layer 312 within each mold cavity. The second layer 314 includes a material having a second strength that is lower than the reference strength and a second modulus that is lower than the reference modulus, thereby enhancing the mechanical properties of the chip packaging structure by effectively managing mechanical stresses. In some implementations, the second layer 314 may be made from materials such as Die Attach Film (DAF), underfill materials, or low-modulus polymers, including silicone and polyurethane. These materials are selected for their ability to absorb and distribute stress, thereby protecting the integrity of the overall structure. The thickness of the second layer 314 may range from about 30 μm to about 100 μm.

The preparation method for the second layer 314 involves depositing a chosen material onto the first layer 312 within the mold cavities of the mold 300b. This can be achieved through various fabrication techniques such as spin coating, screen printing, or dispensing, depending on the specific material used. The deposition process ensures that the second layer 314 conforms to the shape of the first layer 312 and achieves uniform thickness and consistent mechanical properties across all the layers formed.

Once the second layer 314 is deposited and solidified within the mold 300b, it works in conjunction with the first layer 312 to enhance the mechanical stability and strength of the chip packaging structure. The combination of these layers provides a robust foundation for further assembly, ensuring the reliability and durability of the semiconductor device.

In some implementations, as shown in FIG. 3e, a third layer 316 can be formed on the surface of the second layer 314.

The third layer 316 is deposited on top of the second layer 314 within each mold cavity. The third layer 316 includes a material having a third strength less than the second strength and a third modulus less than the second modulus. Suitable materials for the third layer 316 include softer polymers or materials with lower mechanical properties, which can provide additional stress relief and protection for the underlying layers. The thickness of the third layer 316 may range from about 30 μm to about 100 μm. The third layer 316 is deposited using similar fabrication techniques as that for depositing the second layer 314, ensuring that it conforms to the shape of the underlying layers and achieves uniform thickness and consistent mechanical properties across all layers.

In some implementations, as shown in FIG. 3e, a surface area of the first layer 312 is the largest among the three layers, providing a strong foundation for the subsequent layers; a surface area of the second layer 314 is smaller than the surface area of the first layer 312, forming a tiered structure that aids in stress distribution; and a surface area of the third layer 316 is smaller than the surface area of the second layer 314, forming an inverted triangle configuration that optimizes mechanical properties. This configuration of first, second, and third layers (312, 314, 316) provides robust protection for the chip packaging structure, enhancing its mechanical stability and strength. The combination of these layers, each with specific material properties and thicknesses, ensures optimal performance and reliability of the semiconductor device.

Referring back to FIG. 4, operation 404 may further include step 4043: filling the mold with a compound material.

Once the first, second, and third layers (312, 314, and 316) are deposited and solidified, the entire mold 300b is then filled with a compound material to form compound layer 310 as shown in FIG. 3f. This compound material encapsulates all the layers within each mold cavity. The compound material includes materials such as epoxy resins, silicone compounds, or other encapsulating materials known for their excellent adhesion and mechanical properties. The mold 300b is filled with the compound material, ensuring that it flows around and fully encapsulates the first layer 312, the second layer 314, and the third layer 316.

Referring back to FIG. 4, operation 404 may further include step 4044: placing the die assembly into the compound material.

Placing the die assembly 300a into the compound material can be accomplished through various methods, ensuring precise positioning and effective encapsulation. In some implementations, a “pick-and-place” method may be used, where robotic arms equipped with vacuum or mechanical grippers accurately place the die assembly 300a into pre-determined positions within the mold 300b filled with the compound material. This method allows for high precision and repeatability, essential for maintaining the integrity of the chip packaging structure. In some implementations, a placement template may be used to hold the die assembly 300a in correct orientation and alignment, which may be pressed into the compound material, such that the die assembly 300a is encapsulated by the compound material. The placement template can then be removed once the compound material partially cures, leaving the die assembly 300a positioned in the mold 300b. Other methods may be used to encapsulate the die assembly 300a with the compound material, which is not limited herein.

Referring back to FIG. 4, operation 404 may further include step 4045: transforming the compound material into a compound layer.

After the compound material encapsulates the die assembly 300a (in some implementations also the controller 306) within the mold 300b, a curing process may be initiated to transform the compound material into compound layer 310. Curing can be achieved through various methods depending on the specific compound material. One common method involves applying heat in a controlled environment, such as an oven, where temperatures are precisely regulated to ensure thorough curing without damaging the encapsulated components. Another method involves the use of ultraviolet (UV) light, particularly for UV-curable resins, where the mold is exposed to UV radiation to trigger the curing reaction. In some implementations, a combination of heat and UV light may be used to achieve optimal curing. In some implementations, a chemical curing agent may be mixed with the compound material before encapsulation, initiating a curing process that progresses over time at room temperature or accelerated at elevated temperatures. Each of these curing methods ensures that the compound material forms a robust, protective compound layer 310 around the die assembly 300a. The compound layer 310 has the reference strength and the reference modulus. In some implementations, the compound layer 310 has the reference strength in a range of about 170 MPa to about 220 MPa, for example, about 170 MPa, 180 MPa, 190 MPa, 200 MPa, 210 MPa, or 220 MPa. In some implementations, the compound layer 310 has the reference modulus in a range of about 20 GPa to about 30 GPa, for example, about 20 GPa, 21 GPa, 22 GPa, 23 GPa, 24 GPa, 25 GPa, 26 GPa., 27 GPa, 28 GPa, 29 GPa, or 30 GPa.

After curing, the entire mold 300b, with the encapsulated die assembly 300a, is cut to separate each mold cavity into individual chip packaging structures 300 as shown in FIG. 3g. This cutting process is typically performed using precision dicing saws or laser cutters to ensure that each chip packaging structure 300 is accurately formed and separated, ready for integration into semiconductor devices.

As shown in FIG. 3g (cross-section side view from X-Z plane) and FIG. 3g′ (top view from X-Y plane), chip packaging structure 300 includes packaging substrate 302, the one or more dies 304, controller 306, solder balls 308, compound layer 310, first layer 312, second layer 314, and third layer 316. The packaging substrate 302 serves as the foundation for the entire chip packaging structure 300, providing support and electrical connectivity. The one or more dies 304 are the primary semiconductor components that perform the desired functions of the chip. Positioned beside the one or more dies 304, the controller 306 manages and coordinates the operation of the one or more dies 304. Solder balls 308 are attached to the bottom surface of the packaging substrate 302, facilitating electrical connections between the chip packaging structure 300 and an external circuit board. The compound layer 310 encapsulates the one or more dies 304 and controller 306, providing mechanical support and environmental protection.

As shown in FIG. 3g and FIG. 3g′, the first layer 312 is positioned adjacent to the top surface of the compound layer 310, offering additional mechanical strength due to its high-strength material composition, such as metal alloys or high-modulus polymers. The first layer 312 has the largest surface area among the layers, ensuring a robust foundation. The second layer 314, positioned between the first layer 312 and the one or more dies 304, is made from materials with a lower modulus to help manage mechanical stresses, such as Die Attach Film (DAF) or low-modulus polymers like silicone. The second layer 314 has a smaller surface area than the first layer 312, contributing to a tiered structure that aids in stress distribution. The third layer 316, attached to second layer 314, is designed to provide further stress relief and protection with materials that have even lower modulus. The surface area of the third layer 316 is smaller than that of the second layer 314, forming an inverted triangle configuration that optimizes mechanical properties. This multi-layer configuration ensures optimal mechanical stability and performance of the chip packaging structure, with each layer tailored to address specific mechanical challenges. The combination of these elements forms a robust and reliable chip packaging structure capable of maintaining performance under various conditions.

The above exemplary chip packaging structure can be used to form various products of memory system, such as Universal Flash Memory (UFS), Embedded Multimedia Card (eMMC), Personal Computer Memory (PC) Card, CF Card, Smart Media (SM) Card, Memory Stick, Multimedia Card (MMC), SD Card, SSD, etc. The controller in the chip package structure can control the operations of one or more dies, such as read, erase, and program. The controller can also be configured to manage various functions, including but not limited to bad block management, garbage collection, wear leveling, etc. Any other suitable functions may also be performed by the controller, such as formatting the dies. The controller may communicate with external devices according to a particular communication protocol. For example, the controller can communicate with external devices through at least one of various interface protocols, such as USB protocol, MMC protocol, peripheral component interconnect (PCI) protocol, serial bus protocol, Advanced Technology Attachment (ATA) protocol, Serial-ATA protocol, Parallel-ATA20 protocol, Small Computer Small Interface (SCSI) protocol, Enhanced Small Disk Interface (ESDI) protocol, Integrated Drive Electronics (IDE) agreement, etc.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is

1. A chip packaging structure, comprising:
one or more dies stacked on a packaging substrate in a vertical direction; and
a packaging body surrounding the one or more dies,
wherein the packaging body comprises:
a compound layer in direct contact with the one or more dies, wherein the compound layer comprises a material having a reference strength and a reference modulus;
a first layer adjacent to a top surface of the packaging body, wherein the first layer comprises a material having a first strength and a first modulus, and the first strength being greater than the reference strength; and
a second layer positioned between the first layer and the one or more dies along the vertical direction, wherein the second layer comprises a material having a second strength and a second modulus, and the second modulus being less than the reference modulus.

2. The chip packaging structure of claim 1, wherein the first layer has a first surface area, the second layer has a second surface area, and the first surface area is larger than the second surface area.

3. The chip packaging structure of claim 1, wherein the first layer has a first surface area, the second layer has a second surface area, and the first surface area is smaller than the second surface area.

4. The chip packaging structure of claim 1, wherein the packaging body further comprises:
a third layer attached to the second layer, wherein the third layer comprises a material having a third strength and a third modulus, the third strength being less than the second strength, the second strength being less than the reference strength, the third modulus being less than the second modulus, and the first modulus being greater than the reference modulus.

5. The chip packaging structure of claim 1, wherein the packaging body further comprises multiple layers attached to the second layer, wherein:
a strength of each of the multiple layers is less than the strength of the second layer, decreasing from a layer furthest from the packaging substrate to a layer closest to the packaging substrate along the vertical direction; and
a modulus of each of the multiple layers is less than the second modulus of the second layer, increasing from a layer closest to the packaging substrate to a layer furthest from the packaging substrate along the vertical direction.

6. The chip packaging structure of claim 1, wherein the material of the first layer comprises a metal alloy, and the material of the second layer comprises a polymer.

7. The chip packaging structure of claim 1, wherein the one or more dies comprise at least one of a NAND die or a DRAM die.

8. The chip packaging structure of claim 7, further comprising a controller configured to control the one or more dies, wherein the controller is positioned on the packaging substrate and beside the one or more dies.

9. The chip packaging structure of claim 1, wherein the second layer has a curved surface towards the one or more dies.

10. The chip packaging structure of claim 9, wherein the second layer covers a bottom surface and side surfaces of the first layer.

11. The chip packaging structure of claim 9, wherein:
the second layer covers a bottom surface of the first layer; and
the first layer has curved side surfaces in contact with the compound layer.

12. A chip packaging structure, comprising:
one or more dies on a packaging substrate; and
a packaging body surrounding the one or more dies,
wherein the packaging body comprises:
a compound layer in direct contact with at least one of the one or more dies, wherein the compound layer comprises a material having a reference strength and a reference modulus;
a first layer adjacent to a top surface of the packaging body, wherein the first layer comprises a material having a first strength and a first modulus, and the first strength being greater than the reference strength; and
a second layer positioned between the first layer and the one or more dies, wherein the second layer comprises a material having a second strength and a second modulus, and the second modulus being less than the reference modulus,
wherein a surface area of the second layer is smaller than a surface area of the first layer.

13. The chip packaging structure of claim 12, wherein the packaging body further comprises:
a third layer positioned between the second layer and the one or more dies, wherein the third layer comprises a material having a third strength and a third modulus, the third strength being less than the second strength, the third modulus being less than the second modulus, and a surface area of the third layer is smaller than the surface area of the second layer.

14. The chip packaging structure of claim 12, wherein the packaging body further comprises multiple layers attached to the second layer, wherein:
a strength of each of the multiple layers is less than the second strength of the second layer, decreasing from a layer furthest from the packaging substrate to a layer closest to the packaging substrate; and
a modulus of each of the multiple layers is less than the second modulus of the second layer, increasing a layer closest to the packaging substrate to a layer furthest from the packaging substrate.

15. A method of forming a chip packaging structure, comprising:
stacking one or more dies on a packaging substrate in a vertical direction; and
forming a packaging body surrounding the one or more dies, wherein the packaging body comprises:
a compound layer in direct contact with the one or more dies, wherein the compound layer comprises a compound material having a reference strength and a reference modulus;
a first layer adjacent to a top surface of the packaging body, wherein the first layer comprises a material having a first strength and a first modulus, and the first strength being greater than the reference strength; and
a second layer positioned between the first layer and the one or more dies along the vertical direction, wherein the second layer comprises a material having a second strength and a second modulus, and the second modulus being less than the reference modulus.

16. The method of claim 15, wherein forming the packing body comprises:
forming a first layer in a mold;
forming a second layer attached to the first layer along the vertical direction;
filling the mold with the compound material;
placing the one or more dies into the compound material; and
transforming the compound material into the compound layer.

17. The method of claim 16, wherein forming the packing body further comprises:
forming the first layer having a first surface area; and
forming the second layer having a second surface area, wherein the first surface area is larger than the second surface area.

18. The method of claim 16, wherein forming the packing body further comprises:
forming the first layer having a first surface area; and
forming the second layer having a second surface area, wherein the first surface area is smaller than the second surface area.

19. The method of claim 16, wherein forming the packaging body further comprises:
before filling the mold with the compound material, forming a third layer attached to the second layer, wherein the third layer comprises a material having a third strength and a third modulus, the third strength being less than the second strength, and the third modulus being less than the second modulus.

20. The method of claim 16, wherein forming the packaging body further comprises:
before filling the mold with the compound material, forming multiple layers attached to the second layer, wherein:
a strength of each of the multiple layers is less than the strength of the second layer, decreasing from a layer furthest from the packaging substrate to a layer closest to the packaging substrate along the vertical direction; and
a modulus of each of the multiple layers is less than the second modulus of the second layer, increasing from a layer closest to the packaging substrate to a layer furthest from the packaging substrate along the vertical direction.
